(19) United States
(12) Patent Application Publication
(10) Pub. No.: US 2023/0131590 A1
(43) Pub. Date: Apr. 27, 2023

(54) FOLDABLE MOBILE TERMINAL, AND HEAT DISSIPATION SYSTEM AND HOUSING THEREOF

(71) Applicant: WUHAN CHINA STAR OPTPELECTRONICS SEMICONDUCTOR DISPLAY TECHNOLOGY CO., LTD., Wuhan (CN)

(72) Inventor: Feng DING, Wuhan (CN)

(73) Assignee: WUHAN CHINA STAR OPTPELECTRONICS SEMICONDUCTOR DISPLAY TECHNOLOGY CO., LTD., Wuhan (CN)

(21) Appl. No.: 17/045,184

(22) PCT Filed: May 14, 2020
(86) PCT No.: PCT/CN2020/090358

§ 371 Date: Oct. 5, 2020

(30) Foreign Application Priority Data
Mar. 5, 2020 (CN) 202010146262.4

(51) Int. Cl. H05K 7/20; H04M 1/02

(52) U.S. Cl. CPC H05K 7/2039; H04M 1/0216; H04M 1/0249

(57) ABSTRACT

The present invention provides a foldable mobile terminal, and a heat dissipation system and a housing of the foldable mobile terminal. The heat dissipation system includes a heat dissipation hole, a baffle, and a rotating shaft. The heat dissipation hole is defined on the housing of the foldable mobile terminal. When the foldable mobile terminal needs heat dissipation, the baffle rotates to open the heat dissipation hole for the heat dissipation. When the heat dissipation is not required, the baffle closes the heat dissipation hole to prevent foreign matters from entering an interior of the foldable mobile terminal through the heat dissipation hole and affecting performance of the foldable mobile terminal and causing failure.

### FIELD OF INVENTION

The present invention relates to the field of mobile terminals, and in particular, to a foldable mobile terminal, and a heat dissipation system and a housing of the foldable mobile terminal.

### BACKGROUND OF INVENTION

With development of portable electronic devices, display screens of mobile terminals such as mobile phones and tablets have become larger and larger. Although large screens can simultaneously display more content for users, they also bring problems such as large size of electronic device, large occupied space, and poor portability, which restrict development of large-screen portable electronic devices. In order to take into account both portability and large screen of each electronic device, electronics with folding screen have emerged.

With maturity of flexible panel technologies, flexible panels can already be mass-produced, and provide strong support for design and production of foldable screens. At present, according to designs of each foldable mobile terminal manufacturer, heat dissipation of the foldable mobile terminal is achieved by providing heat dissipation holes. Although the heat dissipation holes have a good heat dissipation effect under normal working conditions, foreign matters such as dust and moisture from outside can easily enter an interior of the foldable mobile terminal from the heat dissipation holes, which affects performance of the foldable mobile terminal. Moreover, when the foldable mobile terminal is in a folded state, once the foreign matters enter between folded screens, the screens of the foldable mobile terminal will be damaged.

Therefore, how to prevent the foreign matters from entering the heat dissipation holes on a basis of ensuring a basic function of heat dissipation, and meanwhile prevent the foreign matters from entering between the folded screens in the folded state have become technical problems to be solved urgently and a focus of continuous research.

### Technical Problem

Embodiments of the present invention provide a foldable mobile terminal, and a heat dissipation system and a housing of the foldable mobile terminal. A baffle, a rotating shaft, and a fixing member are disposed in a heat dissipation hole. The rotating shaft drives the baffle to rotate to realize an opening and closing of the heat dissipation hole. The baffle opens the heat dissipation hole during heat dissipation, and closes the heat dissipation hole when the heat dissipation is not required, in a bid to ensure basic functions of the heat dissipation and prevent foreign matters from entering the heat dissipation hole, so as not to affect performance of the foldable mobile terminal. Meanwhile, sealing members and grooves are provided on two foldable housings respectively to ensure sealing between the two housings when the foldable mobile terminal is in a folded state to prevent the foreign matters from entering a folded screen, and to prevent damage to the screen caused by the foreign matters, so as to solve a problem of the foreign matters easily entering the heat dissipation holes and affecting the performance of the foldable mobile terminal and causing damage to the screen when the foreign matters enter the folded screen in the folded state.

### Technical Solution

To this end, embodiments of the present invention provide following technical solutions:

According to a first aspect of the present invention, a heat dissipation system of a foldable mobile terminal is provided. The heat dissipation system comprises a heat dissipation hole, a baffle, and a rotating shaft, wherein the heat dissipation hole is defined on a housing of the foldable mobile terminal, the heat dissipation hole comprises a centrally symmetric and axisymmetric structure, the baffle and the rotating shaft are disposed in the heat dissipation hole, the rotating shaft is rotatably connected to the housing, the rotating shaft is perpendicular to an extending direction of the heat dissipation hole, the rotating shaft is connected with a driving member, the driving member is used to drive the rotating shaft to rotate in the heat dissipation hole, the baffle is fixedly connected with the rotating shaft, and the baffle is used to open or close the heat dissipation hole.

Further, both number of the baffle and the rotating shaft are one, the rotating shaft is close to a side wall of the heat dissipation hole, and the rotating shaft is fixedly connected to an edge of an inner end of the baffle.

Further, both the number of the baffle and the rotating shaft are two, the two baffles are disposed symmetrically, the two rotating shafts are disposed symmetrically, the two rotating shafts are respectively close to two opposite side walls of the heat dissipation hole, and the rotating shafts are respectively fixedly connected to an edge of an inner end of the baffle.

Further, the heat dissipation system 10 further comprises a fixing member, the fixing member is fixed on a wall of the heat dissipation hole, and the fixing member is used to fix the baffle rotating in the heat dissipation hole.

Further, an end surface of the heat dissipation hole is square.

Further, the heat dissipation system further comprises a current sensor electrically connected to a circuit board of the foldable mobile terminal, wherein the current sensor is communicatively connected to a central processor of the foldable mobile terminal, and the central processor is communicatively connected to the driving member.

Further, the heat dissipation system further comprises a temperature sensor, wherein the temperature sensor is fixed in the foldable mobile terminal, and the temperature sensor and the driving member are respectively communicatively connected to a central processor of the foldable mobile terminal.

According to a second aspect of the present invention, a housing of a foldable mobile terminal is provided. The housing of the foldable mobile terminal comprises a first housing and a second housing, wherein the first housing is fixedly connected to a first support plate, the second housing is fixedly connected to a second support plate, and the first support plate and the second support plate are hinged, and wherein the housing of the foldable mobile terminal further comprises any of the above-mentioned heat dissipation system, and a plurality of the heat dissipation systems are respectively fixed on the first housing and the second housing.

Further, a plurality of sealing members are fixed on an edge of a top surface of the first housing, and a plurality of grooves matching the sealing member are defined on an edge of a top surface of the second housing.

According to a third aspect of the present invention, a foldable mobile terminal is provided. The foldable mobile terminal comprises the housing of the foldable mobile terminal described in the second aspect above. The housing of the foldable mobile terminal comprises the first housing and the second housing, the first housing is fixedly connected to the first support plate, the second housing is fixedly connected to the second support plate, and the first support plate and the second support plate are hinged, and wherein the housing of the foldable mobile terminal further comprises any of the above-mentioned heat dissipation system, and the plurality of the heat dissipation systems are respectively fixed on the first housing and the second housing.

Further, a plurality of sealing member are fixed on an edge of a top surface of the first housing, and a plurality of grooves matching the sealing member are defined on an edge of a top surface of the second housing.

### Beneficial Effect

Beneficial effects of the present invention are:

(1) A heat dissipation system of a foldable mobile terminal provided by the present invention is provided with a rotating shaft and a baffle in the heat dissipation hole, a driving shaft drives the rotating shaft to rotate in the heat dissipation hole, and the rotating shaft drives the baffle to rotate, thereby realizing opening or closing of the heat dissipation hole. When heat dissipation is required, the driving member drives the rotating shaft to drive the baffle to open the heat dissipation hole to dissipate heat. The heat dissipation system further comprises a fixing member. The opened baffle is fixed by the fixing member on a wall of the heat dissipation hole. The structure is reliable and the heat dissipation is stable. When no heat dissipation is required, the driving member drives the rotating shaft to drive the baffle to close the heat dissipation hole to prevent dust, moisture, and other foreign matters from entering the foldable mobile terminal through the heat dissipation holes to prevent performance of the foldable mobile terminal from being affected and causing failure.

(2) A housing of the foldable mobile terminal provided by the present invention is provided with a plurality of sealing members disposed on one of the housings and a plurality of grooves matching the sealing members provided on another housing. When the foldable mobile terminal is in a folded state, the sealing members on one of the housing are embedded into the grooves in the other housing, the sealing members and the grooves close tightly to maintain a seal between the two housings, and to prevent dust and other foreign matters from entering a folded screen and damaging it.

### DESCRIPTION OF DRAWINGS

In order to more clearly illustrate the embodiments or the technical solutions in the prior art, a brief introduction of the drawings used in the embodiments or the prior art description will be briefly described below. Obviously, the drawings in the following description are only some of the embodiments of the invention, and those skilled in the art can obtain other drawings according to the drawings without any creative work.

FIG. 1 is a schematic structural view of an embodiment of a heat dissipation system of a foldable mobile terminal in an open state.

FIG. 2 is a schematic structural view of an embodiment of the heat dissipation system of the foldable mobile terminal in a closed state.

FIG. 3 is a schematic structural view of another embodiment of the heat dissipation system of the foldable mobile terminal in the open state.

FIG. 4 is a schematic structural view of another embodiment of the heat dissipation system of the foldable mobile terminal in the closed state.

FIG. 5 is a schematic structural view of a housing of the foldable mobile terminal in an unfolded state provided by the present invention.

FIG. 6 is a schematic structural view of the housing of the foldable mobile terminal in a folded state provided by the present invention.

FIG. 7 is a schematic view of a connection relationship between a sealing member and the housing.

In the drawings,

10: heat dissipation system; 1: heat dissipation hole; 2: first baffle; 2′: second baffle; 2″: third baffle; 3: first rotating shaft; 3′: second rotating shaft; 3″: third rotating shaft; 4: first fixing member; 4′: second fixing member; 4″: third fixing member; 5: first stop; 5′: second stop; 5″: third stop; 100: first housing; 200: second housing; 20: sealing member; 21: positioning rod; 22: clamping hole; 30: groove.

### DETAILED DESCRIPTION OF PREFERRED EMBODIMENTS

The following is a clear and complete description of a technical solution of a foldable mobile terminal, and a heat dissipation system and a housing of the foldable mobile terminal provided by the present invention in conjunction with drawings of the specification. Obviously, the described embodiments are only a portion of the embodiments of the present invention, but not all the embodiments. Based on the embodiments of the present invention, all other embodiments obtained by those skilled in the art without making creative efforts fall within a protection scope of the present invention.

In the description of the present invention, it is to be understood that the terms “center,” “longitudinal,” “lateral,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise,” and the like are used in the orientations and positional relationships indicated in the drawings for convenience in describing the present invention and for simplicity in description, and are not intended to indicate or imply that the referenced devices or elements must have a particular orientation, be constructed in a particular orientation, and be operated in a particular manner, and are not to be construed as limiting the present invention. Furthermore, the terms “first,” “second,” and “third” are used for descriptive purposes only and are not to be construed as indicating or implying relative importance or implicitly indicating the number of technical features indicated. Thus, features defined as “first,” “second,” and “third” may explicitly or implicitly include one or more of the described features. In the description of the present application, “plurality” means two or more unless specifically limited otherwise.

In the description of the present invention, it is to be noted that, unless otherwise explicitly specified or limited, the terms “mounted,” “connected,” and “linked” are to be construed broadly, e.g., as meaning either a fixed connection, a removable connection, or an integral connection; may be mechanically connected, may be electrically connected or may be in communication with each other; either directly or indirectly through intervening media, either internally or in any other relationship. The specific meaning of the above terms in the present invention can be understood by those of ordinary skill in the art as appropriate.

In the present invention, the term “exemplary” is used to mean “used as an example, illustration, or illustration.” Any embodiment described as “exemplary” in the present invention is not necessarily to be construed as more preferred or advantageous than other embodiments. In order to enable any person skilled in the art to implement and use the present invention, the following description is given. In the following description, the invention sets out details for the purpose of explanation. It should be understood that those of ordinary skill in the art may recognize that the present invention can be implemented even without using these specific details. In other examples, well-known structures and processes will not be elaborated in detail to avoid unnecessary details that obscure the description of the present invention. Therefore, the present invention is not intended to be limited to the illustrated embodiments, but should be consistent with the widest scope consistent with the principles and features disclosed in the present invention.

An embodiment of the present invention provides a heat dissipation system of a foldable mobile terminal. The heat dissipation system 10 comprises a heat dissipation hole 1, a baffle, and a rotating shaft. The heat dissipation hole 1 is defined on a housing of the foldable mobile terminal. The heat dissipation hole 1 comprises a centrally symmetric and axisymmetric structure. That is, the heat dissipation hole has a regular shape. The baffle and the rotating shaft are disposed in the heat dissipation hole 1. The rotating shaft is rotatably connected to the housing, and the rotating shaft is perpendicular to an extending direction of the heat dissipation hole 1. The rotating shaft is connected with a driving member. The driving member is used to drive the rotating shaft to rotate in the heat dissipation hole 1. The baffle is fixedly connected with the rotating shaft. Preferably, an inner edge of the baffle is fixedly connected to the rotating shaft. The baffle is used to open or close the heat dissipation hole 1. The baffle rotates with a rotation of the rotating shaft to realize an opening and closing of the heat dissipation hole 1. Heat dissipation is achieved when the heat dissipation hole 1 is opened to reduce a temperature of the foldable mobile terminal. When the heat dissipation hole 1 is closed, external dust, moisture, and other foreign matters are prevented from entering an interior of the foldable mobile terminal, so as not to affect performance of internal devices of the foldable mobile terminal.

The heat dissipation system further comprises a fixing member. The fixing member is fixed on a wall of the heat dissipation hole 1. The fixing member is used to fix the baffle rotating in the heat dissipation hole. The fixing member is disposed at a rear portion of the baffle that rotates to an interior of the heat dissipation hole to a maximum angle. During a rotation of the baffle with a rotation of the rotating shaft toward the interior of the heat dissipation hole 1, an opening area of the heat dissipation hole 1 increases. When the baffle rotates to the interior of the heat dissipation hole 1 to the maximum angle, the heat dissipation hole 1 is fully opened. At this time, the fixing member on the wall of the heat dissipation hole 1 fixes the baffle to prevent the baffle activity from closing the heat dissipation hole 1 due to a movement or vibration of the foldable mobile terminal and affecting a heat dissipation effect. The fixing member ensures that the heat dissipation hole 1 is in a stable open state and ensures a good heat dissipation effect.

The fixing member is preferably an electromagnetic strip. The fixing member is electrically connected to a battery of the foldable mobile terminal. During the heat dissipation, the electromagnetic strip is energized, and the electromagnetic strip adsorbs and fixes the baffle. When the heat dissipation is not required, the electromagnetic strip is powered off and magnetism disappears. The baffle is driven by the rotating shaft to close the heat dissipation hole 1.

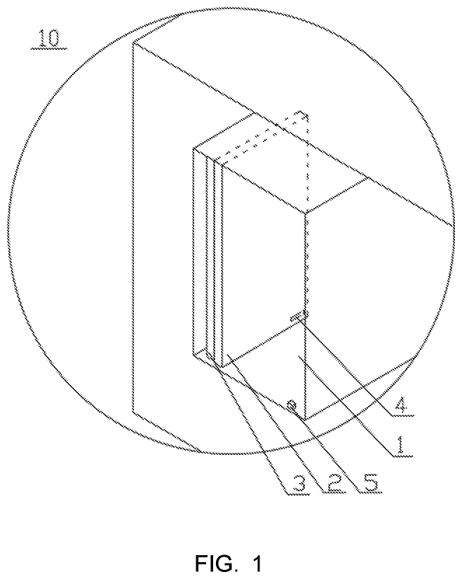

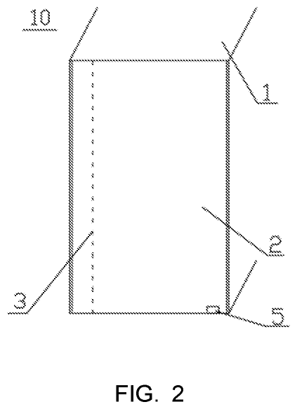

Please refer to FIG. 1 and FIG. 2. FIG. 1 is a schematic structural view of an embodiment of the heat dissipation system of the foldable mobile terminal in an open state. FIG. 2 is a schematic structural view of an embodiment of the heat dissipation system of the foldable mobile terminal in a closed state. The embodiments provide the heat dissipation system of the foldable mobile terminal. The heat dissipation system comprises the heat dissipation hole 1, and the baffle, the rotating shaft, and the fixing member disposed in the heat dissipation hole 1. That is, the heat dissipation system 10 comprises the heat dissipation hole 1, a first baffle 2, a first rotating shaft 3, and a first fixing member 4. The first baffle 2, the first rotating shaft 3, and the first fixing member 4 are disposed in the heat dissipation hole 1. The first rotating shaft 3 is rotatably connected to the housing with the heat dissipation hole 1. An end face of the heat dissipation hole 1 is preferably square. Two ends of the first rotating shaft 3 are respectively embedded in an upper wall and a lower wall of the heat dissipation hole 1, and the first rotating shaft 3 is rotatably connected to the housing with the heat dissipation hole 1. The first rotating shaft 3 is close to one of side walls of the heat dissipation hole 1. The first rotating shaft 3 is connected to a driving member, and the driving member drives the first rotating shaft 3 to rotate in the heat dissipation hole 1. The first rotating shaft 3 is fixedly connected to an edge of an inner face of the first baffle 2 such that when the first baffle 2 rotates with the first rotating shaft 3 to a direction perpendicular to an extending direction of the heat dissipation hole 1, the first baffle 2 can almost completely close the heat dissipation hole 1 to prevent excessive gaps and have good sealing, and effectively prevent the external dust, moisture, and other foreign matters from entering an interior of the foldable mobile terminal. The first fixing member 4 is fixed on a side wall of the heat dissipation hole 1 close to the first rotating shaft 3 and parallel to the first rotating shaft 3. When the first baffle 2 rotates with the first rotating shaft 3 to the interior of the heat dissipation hole 1 at a maximum angle, the heat dissipation hole 1 has a largest open area. The first fixing member 4 fixes the first baffle 2 at this time to prevent movement of the foldable mobile terminal or vibration caused by the movement of the first baffle 2 to close the heat dissipation hole 1, thereby affecting the heat dissipation. The first fixing member 4 ensures that the heat dissipation hole 1 is in the stable open state and ensures the good heat dissipation effect.

Specifically, as shown in FIG. 1, both ends of the first rotating shaft 3 are rotatably connected to upper and lower walls of the housing where the heat dissipation hole 1 is provided. The first rotating shaft 3 is fixed on a leftmost side of the heat dissipation hole 1. The first rotating shaft 3 is fixedly connected to a leftmost edge of an inner end surface of the first baffle 2. The first fixing member 4 is fixed on a left side wall of the heat dissipation hole 1. The first fixing member 4 is disposed at a rear portion of the first baffle 2 that opens to the interior of the heat dissipation hole by the maximum angle. As shown in FIG. 2, the first baffle 2 can close the end surface of the heat dissipation hole 1, and the heat dissipation hole 1 is almost completely closed to prevent the foreign matters from entering.

Preferably, a first stop 5 is provided on a bottom surface of the heat dissipation hole 1. The first stop 5 is close to an opposite side wall of the first rotating shaft 3. The first stop 5 is used to block the first baffle 2 to prevent the first rotating shaft 3 from rotating the first baffle 2 to an outside of the heat dissipation hole 1 due to an excessive rotation. On one hand, this ensures that the first baffle 2 completely closes the heat dissipation hole 1, and on the other hand, prevents the first baffle 2 from rotating out of the heat dissipation hole 1 after the excessive rotation, which affects aesthetics of the foldable mobile terminal and is not easy to carry.

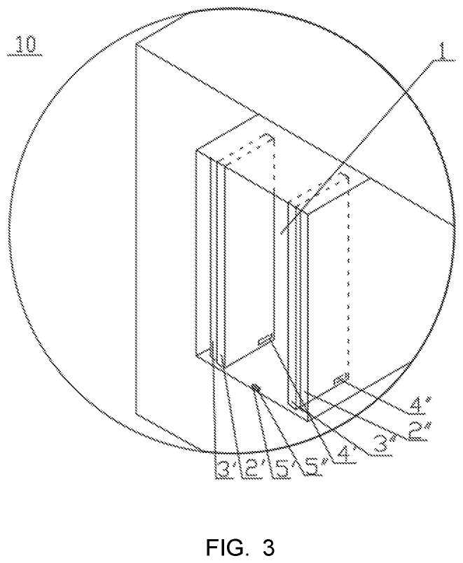

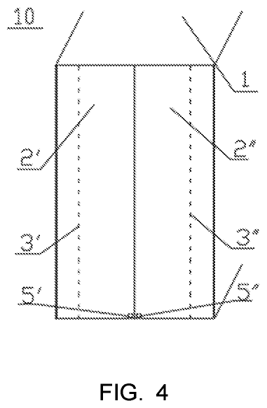

Please refer to FIG. 3 and FIG. 4. FIG. 3 is a schematic structural view of another embodiment of the heat dissipation system of the foldable mobile terminal in the open state. FIG. 4 is a schematic structural view of another embodiment of the heat dissipation system of the foldable mobile terminal in the closed state. The embodiments provide the heat dissipation system of the foldable mobile terminal. The heat dissipation system 10 comprises the heat dissipation hole 1 and two baffles, two rotating shafts, and two fixing members disposed in the heat dissipation hole 1. That is, the heat dissipation system 10 comprises the heat dissipation hole 1, a second baffle 2′, a third baffle 2″, a second rotating shaft 3′, a third rotating shaft 3″, a second fixing member 4′, and a third fixing member 4″. The second baffle 2′, the third baffle 2″, the second rotating shaft 3′, the third rotating shaft 3″, the second fixing member 4′, and the third fixing member 4″ are disposed in the heat dissipation hole 1. The end face of the heat dissipation hole 1 is preferably square. The second baffle 2′ and the third baffle 2″ are arranged symmetrically, the second rotating shaft 3′ and the third rotating shaft 3″ are arranged symmetrically, and the second fixing member 4′ and the third fixing member 4″ are also arranged symmetrically. The second rotating shaft 3′ and the third rotating shaft 3″ are respectively rotatably connected to the upper and lower walls of the housing where the heat dissipation hole 1 is provided. The second rotating shaft 3′ and the third rotating shaft 3″ are respectively close to the two opposite side walls of the heat dissipation hole 1. The second rotating shaft 3′ and the third rotating shaft 3″ are respectively connected to the driving member. A number of the driving member may be one, and the driving member simultaneously drives the second rotating shaft 3′ and the third rotating shaft 3″ to rotate in opposite directions through a transmission mechanism. The number of the driving member can also be two, and the second rotating shaft 3′ and the third rotating shaft 3″ can be synchronously rotated by simultaneously controlling the two driving members. The second rotating shaft 3′ is fixedly connected to an edge of an inner end surface of the second baffle 2′, and the third rotating shaft 3″ is fixedly connected to an edge of an inner end surface of the third baffle 2″. The second shaft 3′ drives the second baffle 2′ while the third shaft 3″ drives the third baffle 2″. When the second rotating shaft 3′ and the third rotating shaft 3″ rotate simultaneously in a direction of a center line of the heat dissipation hole 1, the heat dissipation hole 1 opens. When the second rotating shaft 3′ and the third rotating shaft 3″ turn toward both side walls of the heat dissipation hole 1 at the same time, the heat dissipation hole 1 slowly closes. Until the second baffle 2′ and the third baffle 2″ are side by side, the heat dissipation hole 1 is closed. The second fixing member 4′ is fixed to the side wall of the heat dissipation hole 1 close to the second rotating shaft 3′, and the second fixing member 4′ is used to fix the second baffle 2′. The second fixing member 4′ is disposed at a rear portion of the second baffle 2′ when rotated to the interior of the heat dissipation hole 1 to the maximum angle. The third fixing member 4″ is fixed on the side wall of the heat dissipation hole 1 close to the third rotating shaft 3″, and the third fixing member 4″ is used to fix the third baffle 2″. The third fixing member 4″ is disposed at a rear portion of the third baffle 2″ when rotating to the interior of the heat dissipation hole 1 to the maximum angle. The second fixing member 4′ and the third fixing member 4″ prevent movement or vibration of the foldable mobile terminal to cause movement of the second baffle 2′ and the third baffle 2″ to close the heat dissipation hole 1, thereby affecting the heat dissipation effect. The second fixing member 4′ and the third fixing member 4″ ensure that the heat dissipation hole 1 is in the stable open state and ensure the good heat dissipation effect.

Specifically, as shown in FIG. 3, the second rotating shaft 3′ and the third rotating shaft 3″ are embedded in the upper and lower walls of the heat dissipation hole 1 and are rotationally connected to the housing where the heat dissipation hole 1 is provided. The second rotating shaft 3′ is fixed to the leftmost side of the heat dissipation hole 1, and the third rotating shaft 3″ is fixed on a rightmost side of the heat dissipation hole 1. The second rotating shaft 3′ is fixedly connected to a topmost edge of an inner end of the second baffle 2′, and the third rotating shaft 3″ is fixedly connected to a rightmost edge of an inner end of the third baffle 2″. The second fixing member 4′ is fixed to the left side wall of the heat dissipation hole 1, and the second fixing member 4′ is disposed at the rear portion of the second baffle 2′ which rotates toward the interior of the heat dissipation hole 1 to the maximum angle. The third fixing member 4″ is fixed on a right-side wall of the heat dissipation hole 1, and the third fixing member 4″ is disposed at the rear portion of the third baffle 2″ which rotates toward the interior of the heat dissipation hole 1 to the maximum angle. As shown in FIG. 4, when the second baffle 2′ and the third baffle 2″ are side by side, the end surface of the heat dissipation hole 1 can be closed. The heat dissipation hole 1 is in the closed state to prevent entry of the foreign matters.

Preferably, the bottom surface of the heat dissipation hole 1 is provided with a second stop 5′ and a third stop 5″. The second stop 5′ and the third stop 5″ are preferably fixed side by side in a middle of the bottom surface of the heat dissipation hole 1. The second stop 5′ is used to block the second baffle 2′, and the third stop 5″ is used to block the third baffle 2″ to avoid an excessive rotation of the second baffle 2′ and the third baffle 2″. On one hand, this ensures that the second baffle 2′ and the third baffle 2″ completely close the heat dissipation hole 1, and on the other hand, prevents the second baffle 2′ and the third baffle 2″ from rotating out of the heat dissipation hole 1 after the excessive rotation, which affects the aesthetics of the foldable mobile terminal and is not easy to carry.

In some embodiments, the heat dissipation system 10 further comprises a current sensor. The current sensor is electrically connected to a circuit board of the foldable mobile terminal. The current sensor is communicatively connected to a central processor of the foldable mobile terminal, and the central processor is communicatively connected to the driving member. The driving member is preferably a motor. When the current sensor detects that there is a current through the circuit board, the current sensor transmits a signal to the central processor. Meanwhile, the central processor starts the motor, and the battery supplies power to the electromagnetic strip, the motor drives the rotating shaft to rotate, and the rotating shaft drives the baffle to rotate in the heat dissipation hole 1 at the same time. When the baffle rotates to the interior of the heat dissipation hole 1 to the maximum angle, an opening space of the heat dissipation hole 1 is the largest, and the electromagnetic strip adsorbs and fixes the baffle to keep the heat dissipation hole 1 open and perform a stable heat dissipation. When the current sensor detects that there is no current through the circuit board, the current sensor transmits a signal to the central processor, and the central processor controls the motor to rotate in a reverse direction, and at the same time stops energizing the electromagnetic strip. The magnetism of the magnetic strip disappears, an absorption capacity disappears, and the rotating shaft drives the baffle to rotate to the outside of the heat dissipation hole 1 until the baffle completely closes the heat dissipation hole 1.

In other embodiments, the heat dissipation system 10 further comprises a temperature sensor. The temperature sensor is fixed in the foldable mobile terminal and is used to detect a temperature in the foldable mobile terminal. The temperature sensor and the driving member are respectively communicatively connected to the central processor of the foldable mobile terminal. The driving member is preferably a motor. When the temperature sensor detects that the temperature in the foldable mobile terminal is higher than a first threshold, the central processor starts the motor, and at the same time, the battery supplies power to the electromagnetic strip. The motor drives the rotating shaft to rotate, and the rotating shaft drives the baffle to rotate in the heat dissipation hole 1. When the baffle rotates to the interior of the heat dissipation hole 1 to the maximum angle, the opening space of the heat dissipation hole 1 is the largest, and the electromagnetic strip adsorbs and fixes the baffle to keep the heat dissipation hole 1 open and perform the stable heat dissipation. When the temperature sensor detects that the temperature in the foldable mobile terminal is lower than a second threshold, the central processor controls the motor to rotate in the reverse direction, and at the same time stops energizing the electromagnetic strip. The magnetism of the magnetic strip disappears, the absorption capacity disappears, and the rotating shaft drives the baffle to rotate to the outside of the heat dissipation hole 1 until the baffle completely closes the heat dissipation hole 1.

The heat dissipation system provided by the embodiment of the present invention is not limited to the foldable mobile terminal, and is also applicable to other electronic devices requiring the heat dissipation. The heat dissipation system is versatile.

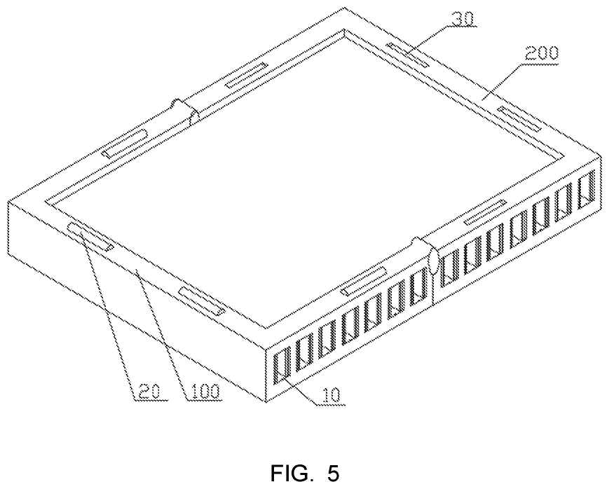

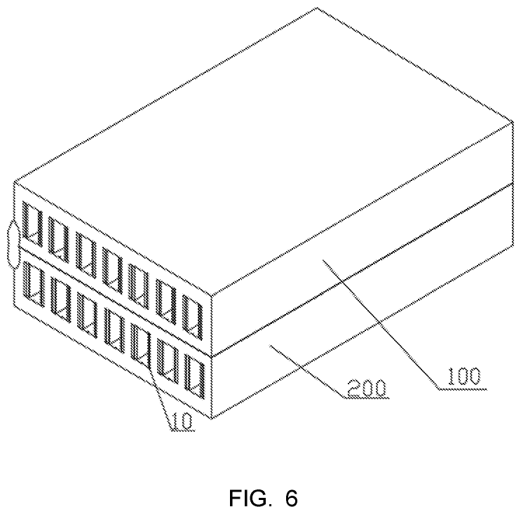

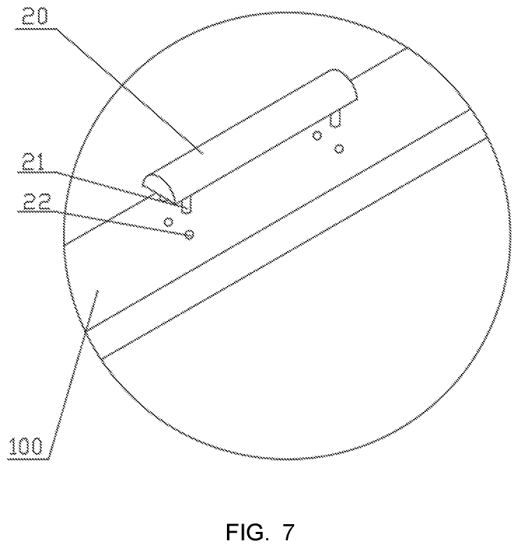

An embodiment of the present invention further provides a housing of the foldable mobile terminal. Please refer to FIG. 5 and FIG. 6. FIG. 5 is a schematic structural view of a housing of the foldable mobile terminal in an unfolded state provided by the present invention. FIG. 6 is a schematic structural view of the housing of the foldable mobile terminal in a folded state provided by the present invention. The housing of the foldable mobile terminal comprises a first housing 100 and a second housing 200. The first housing 100 is fixedly connected to a first support plate (not shown in the drawings). The second housing 200 is fixedly connected to a second support plate (not shown in the drawings). The first support plate and the second support plate are hinged, so that the first housing and the second housing can be folded and aligned. The housings of the foldable mobile terminal further comprise the heat dissipation system 10 according to any one of embodiments. A plurality of the heat dissipation systems 10 are respectively fixed on the first housing 100 and the second housing 200, and preferably fixed on side surfaces of the first housing 100 and the second housing 200. As shown in FIG. 5, a plurality of sealing members 20 is fixed on an edge of a top surface of the first housing 100, and a plurality of grooves 30 matching the sealing members 20 are defined on an edge of a top surface of the second housing 200. Specifically, structures of the first housing 100 and the second housing 200 are the same, and concave surfaces are provided on the top surface. Three sides around the concave surface are convex sides. When the housings of the foldable mobile terminal are in the unfolded state, the concave surface of the first housing 100 and the concave surface of the second housing 200 are aligned and on a same horizontal plane. The three convex sides of the first housing 100 and the three convex sides of the second housing 200 form a closed shape and surround a plane formed by the concave surface of the first housing 100 and the concave surface of the second housing 200. A flexible panel is tiled on the plane where the concave surface of the first housing 100 and the second housing 200 are combined. The convex side of the first housing 100 and the convex side of the second housing 200 surround the flexible panel. The three convex sides of the first housing 100 are all fixed with the sealing members 20, and the three convex sides of the second housing 200 are all provided with corresponding grooves 30. As shown in FIG. 6, when the housings of the foldable mobile terminal are in the folded state, the sealing members 20 on the first housing 100 are embedded in the grooves 30 on the second housing 200. The sealing members 20 and the grooves 30 are tightly closed, so that there is almost no gap between the convex side of the first housing 100 and the convex side of the second housing 200, preventing the foreign matters such as dust from entering a folded screen and damaging the screen. The sealing member 20 is preferably a strip sealing member. As shown in FIG. 7, a positioning rod 21 is provided at a bottom of the sealing member 20. The first housing 100 is provided with a clamping hole 22 matching the positioning rod 21. The positioning rod 21 and the clamping hole 22 have an interference fit to firmly fix the sealing member 20 on the first housing 100. Materials of the sealing member 20 and the positioning rod 21 is preferably rubber.

An embodiment of the present invention further provides the foldable mobile terminal. The foldable mobile terminal comprises the housing of the foldable mobile terminal in any of the foregoing embodiments or the heat dissipation system of the foldable mobile terminal in any of the foregoing embodiments. The foldable mobile terminal can be a portable electronic product with a folding screen, such as a smart phone, smart watch, smart bracelet, tablet, notebook, or smart wearable device (such as smart helmet, smart glasses).

The above are only preferred embodiments of the present invention and are not intended to limit the present invention. Any modifications, equivalent replacements, and simple improvements made on the substance of the present invention shall be included in the protection scope of the present invention.

### INDUSTRIAL APPLICABILITY

In the heat dissipation system of the foldable mobile terminal provided by the present invention, when the heat dissipation is required, the driving member drives the rotating shaft to drive the baffle to open the heat dissipation hole for heat dissipation; when the heat dissipation is not required, the driving member drives the rotating shaft to drive the baffle to close the heat dissipation hole, preventing the foreign matters such as dust and moisture from entering the interior of the foldable mobile terminal through the heat dissipation hole and affecting the performance of the foldable mobile terminal and causing failure. When the foldable mobile terminal is in the folded state, the sealing members on one of the housings are embedded in the grooves on the other housing. The sealing members and the grooves are tightly closed to maintain the seal between the two housings, preventing the foreign matters such as dust from entering the folded screen and damaging the screen. It solves a problem that the foreign matters existing in current foldable mobile terminal easily enter the heat dissipation hole and affect the performance of the foldable mobile terminal, and the foreign matters enter the folded screen and damages the screen in the folded state.

1. A heat dissipation system of a foldable mobile terminal, comprising:
a heat dissipation hole, a baffle, and a rotating shaft, wherein the heat dissipation hole is defined on a housing of the foldable mobile terminal, the heat dissipation hole comprises a centrally symmetric and axisymmetric structure, the baffle and the rotating shaft are disposed in the heat dissipation hole, the rotating shaft is rotatably connected to the housing, the rotating shaft is perpendicular to an extending direction of the heat dissipation hole, the rotating shaft is connected with a driving member, the driving member is used to drive the rotating shaft to rotate in the heat dissipation hole, the baffle is fixedly connected with the rotating shaft, and the baffle is used to open or close the heat dissipation hole.

2. The heat dissipation system of the foldable mobile terminal as claimed in claim 1, wherein both number of the baffle and the rotating shaft are one, the rotating shaft is close to a side wall of the heat dissipation hole, and the rotating shaft is fixedly connected to an edge of an inner end of the baffle.

3. The heat dissipation system of the foldable mobile terminal as claimed in claim 1, wherein both number of the baffle and the rotating shaft are two, the two baffles are disposed symmetrically, the two rotating shafts are disposed symmetrically, the two rotating shafts are respectively close to two opposite side walls of the heat dissipation hole, and the rotating shafts are respectively fixedly connected to an edge of an inner end of the baffle.

4. The heat dissipation system of the foldable mobile terminal as claimed in claim 1, wherein the heat dissipation system further comprises a fixing member, the fixing member is fixed on a wall of the heat dissipation hole, and the fixing member is used to fix the baffle rotating in the heat dissipation hole.

5. The heat dissipation system of the foldable mobile terminal as claimed in claim 1, wherein an end surface of the heat dissipation hole is square.

6. The heat dissipation system of the foldable mobile terminal as claimed in claim 1, further comprising a current sensor electrically connected to a circuit board of the foldable mobile terminal, wherein the current sensor is communicatively connected to a central processor of the foldable mobile terminal, and the central processor is communicatively connected to the driving member.

7. The heat dissipation system of the foldable mobile terminal as claimed in claim 1, further comprising a temperature sensor, wherein the temperature sensor is fixed in the foldable mobile terminal, and the temperature sensor and the driving member are respectively communicatively connected to a central processor of the foldable mobile terminal.

8. A housing of a foldable mobile terminal, comprising:
a first housing and a second housing, wherein the first housing is fixedly connected to a first support plate, the second housing is fixedly connected to a second support plate, and the first support plate and the second support plate are hinged, and wherein the housing of the foldable mobile terminal further comprises the heat dissipation system according to claim 1, and a plurality of the heat dissipation systems are respectively fixed on the first housing and the second housing.

9. The housing of the foldable mobile terminal as claimed in claim 8, wherein a plurality of sealing members are fixed on an edge of a top surface of the first housing, and a plurality of grooves matching the sealing members are defined on an edge of a top surface of the second housing.

10. A foldable mobile terminal, comprising:
the housing of the foldable mobile terminal as claimed in claim 8, wherein the housing of the foldable mobile terminal comprises the first housing and the second housing, the first housing is fixedly connected to the first support plate, the second housing is fixedly connected to the second support plate, and the first support plate and the second support plate are hinged, and wherein the housing of the foldable mobile terminal further comprises the heat dissipation system according to claim 1, and the plurality of the heat dissipation systems are respectively fixed on the first housing and the second housing.

11. The foldable mobile terminal as claimed in claim 10, wherein a plurality of sealing members are fixed on an edge of a top surface of the first housing, and a plurality of grooves matching the sealing members are defined on an edge of a top surface of the second housing.
